(19) United States
(12) Patent Application Publication
(10) Pub. No.: US 2002/0071576 A1
(43) Pub. Date: Jun. 13, 2002

(54) Multiple configuration loudspeaker terminals

(75) Inventor: William S.H. Munro, Glasgow (GB)

Correspondence Address: JENKENS & GILCHRIST, A PROFESSIONAL CORPORATION, 1100 LOUISIANA, SUITE 1800, HOUSTON, TX, 77002-5214, US

(73) Assignee: Linn Products Limited, Glascow (GB)

(21) Appl. No.: 09/929,518

(22) Filed: Aug. 14, 2001

(30) Foreign Application Priority Data
Aug. 15, 2000 (GB) 0019925.7

(51) Int. Cl. H03G 5/00; H04R 1/00; H04R 9/06; H04R 11/02

(52) U.S. Cl. 381/99; 381/409; 381/410

(57) ABSTRACT

An audio loudspeaker comprises: an enclosure; at least two driver units mounted within the enclosure; crossover circuitry located inside the enclosure; and a plurality of input terminals located on the exterior of the enclosure. The input terminals include: first pairs of terminals for each of the driver units, each of the first pairs being connected directly to a respective one of the driver units; a second pair of second terminals having a first crossover circuit connected therebetween and normally electrically isolated from the driver units; and a third pair of third terminals having a second crossover circuit connected therebetween and normally electrically isolated from the driver units. Connector elements are used for interconnecting selected ones of said first, second and third terminals, externally of said enclosure, whereby the crossover circuits may be selectively connected in circuit between one or more of the first terminals and one or more of the driver units.

The present invention relates to audio loudspeakers. More particularly, the invention relates to terminal arrangements for high fidelity (“hi-fi”) loudspeakers whereby loudspeakers may be connected to associated amplifiers using different terminal configurations to enable selection of “passive” or “active” crossover modes and/or different wiring configurations.

A hi-fi loudspeaker conventionally includes at least two electrical-audio transducers or “driver units”, typically comprising at least one high frequency (treble) driver or “tweeter” and at least one low frequency (bass) unit or “woofer”. More sophisticated loudspeakers have additional driver units, which may include additional woofers and/or tweeters, and/or mid-range drivers etc. In all cases, some arrangement is required to process the audio frequency signal input to the loudspeaker into frequency bands, such that the appropriate frequency band is applied to each driver unit. Such arrangements are generally referred to as “crossovers”. A passive crossover comprises passive filter components (resistances, capacitances and inductances) located inside the loudspeaker enclosure. An active crossover comprises active electronic signal processing circuitry. Conventionally, the active crossover circuitry is incorporated into the loudspeaker, as with a passive crossover. However, in some cases, the active crossover is located externally of the loudspeaker enclosure, usually at the amplifier end (i.e. “upstream” of the loudspeaker input terminals); e.g. incorporated into the power amplifiers).

The present invention is particularly concerned with adapting loudspeakers having an internal passive crossover for use with an external active crossover.

Taking a simple two-driver loudspeaker as an example, the loudspeaker typically has two input terminals, a positive and a negative, each of which is connected to each of the two drive units via the passive crossover. The internal passive crossover circuit is used to filter the signals applied to each driver. The passive crossover typically comprises a passive high-pass filter connected between the input terminal and the tweeter and a passive low-pass filter connected between the input terminal and the woofer. The amplifier has a corresponding pair of output terminals, which are connected to the loudspeaker input terminals. Other wiring arrangements are possible. Each driver unit may have its own set of terminals, providing completely separate signal paths from the amplifier(s) to the individual drivers. This is known as “bi-wiring”. The same audio-frequency signal is applied to each set of terminals and each set of terminals has an appropriate passive filter connected between the terminals and the driver unit.

Improved sound reproduction can be achieved by using separate power amplifiers, designed for optimal performance with different frequency bands, with separate signal paths to drive each driver unit. This is known as “bi-amping”. In this case, the complete audio frequency signal is processed and divided into frequency bands upstream of the loudspeaker, typically by circuitry within the power amplifiers. That is, the power amplifiers provide an active crossover function. In these circumstances, the signals output from the power amplifiers should be applied directly to the respective loudspeaker driver units via respective pairs of loudspeaker input terminals, without any intervening passive crossover components.

In the present description, the term “active crossover” will be used to refer to the situation where an active crossover is provided upstream of the loudspeaker, as distinct from a conventional active crossover incorporated into a loudspeaker.

It is desirable to provide users of hi-fi equipment with system components (audio sources, amplification and loudspeakers) which allow structured, progressive upgrading. For example, a user may begin with a system comprising one or more audio sources, an integrated amplifier and loudspeakers with passive crossovers. If the user wishes to upgrade the system by replacing the integrated amplifier with a pre-amplifier and a pair of power amplifiers so as to obtain an active-crossover bi-amped system, it is necessary for the signal paths between the power amplifiers and the driver units of the loudspeakers to be modified to by-pass the existing passive crossover circuitry. With conventional loudspeakers, this requires the loudspeaker enclosure to be opened and the internal circuitry to be re-wired by hand. This is time consuming, may damage the loudspeaker and requires skilled labour.

It will be understood that the various scenarios described above for two-driver loudspeakers also apply to loudspeakers having more than two driver units.

It is an object of the present invention to provide improved loudspeakers having input terminals and associated circuitry configured so as to allow an internal passive crossover to be by-passed without opening the loudspeaker enclosure.

In accordance with one aspect of the invention, there is provided an audio loudspeaker comprising:

an enclosure;

at least two driver units mounted within said enclosure;

crossover circuitry located inside said enclosure; and

a plurality of input terminals located on the exterior of said enclosure; wherein:

said input terminals include a first pair of first terminals for each of said driver units, each of said first pairs of first terminals being connected directly to a respective one of said driver units, a second pair of second terminals having a first crossover circuit connected therebetween and normally electrically isolated from said driver units, and a third pair of third terminals having a second crossover circuit connected therebetween and normally electrically isolated from said driver units.

Preferably, the loudspeaker further includes at least one connector element for interconnecting selected ones of said first, second and third terminals, externally of said enclosure, whereby said crossover circuits may be selectively connected in circuit between one or more of said first terminals and one or more of said driver units.

Preferably, said connector element comprises a generally planar member having a plurality of apertures therein corresponding in number and position to said plurality of input terminals, whereby said planar member may be mounted on said terminals with said terminals projecting through said apertures, said planar member having electrically conductive elements on at least one side thereof interconnecting selected ones of said apertures in a predetermined configuration.

Preferably also, said planar member has different patterns of electrically conductive elements on each side thereof interconnecting selected ones of said apertures in different predetermined configurations.

Preferably also, said planar member is provided with indicia on at least one side thereof indicating a mode of loudspeaker operation corresponding to the pattern of electrically conductive elements thereon, if any, and indicating the terminals to which amplifier connections should be made.

In accordance with a second aspect of the invention, there is provided a connector board for use with an audio loudspeaker in accordance with the first aspect, said connector board comprising a generally planar member having a plurality of apertures therein corresponding in number and position to said plurality of input terminals of said loudspeaker, whereby said planar member may be mounted on said terminals with said terminals projecting through said apertures, said planar member having electrically conductive elements on at least one side thereof interconnecting selected ones of said apertures in a predetermined configuration.

Preferably, said planar member has different patterns of electrically conductive elements on each side thereof interconnecting selected ones of said apertures in different predetermined configurations.

Preferably also, said planar member is provided with indicia on at least one side-thereof-indicating a mode of loudspeaker operation corresponding to the pattern of electrically conductive elements thereon, if any, and indicating the terminals to which amplifier connections should be made.

Embodiments of the invention will now be described, by way of example only, with reference to the accompanying drawings, in which:

FIG. 1 is a perspective view of one embodiment of a terminal and passive crossover assembly for a two-driver loudspeaker, in accordance with the present invention;

FIG. 2 is a schematic circuit diagram of the assembly of FIG. 1;

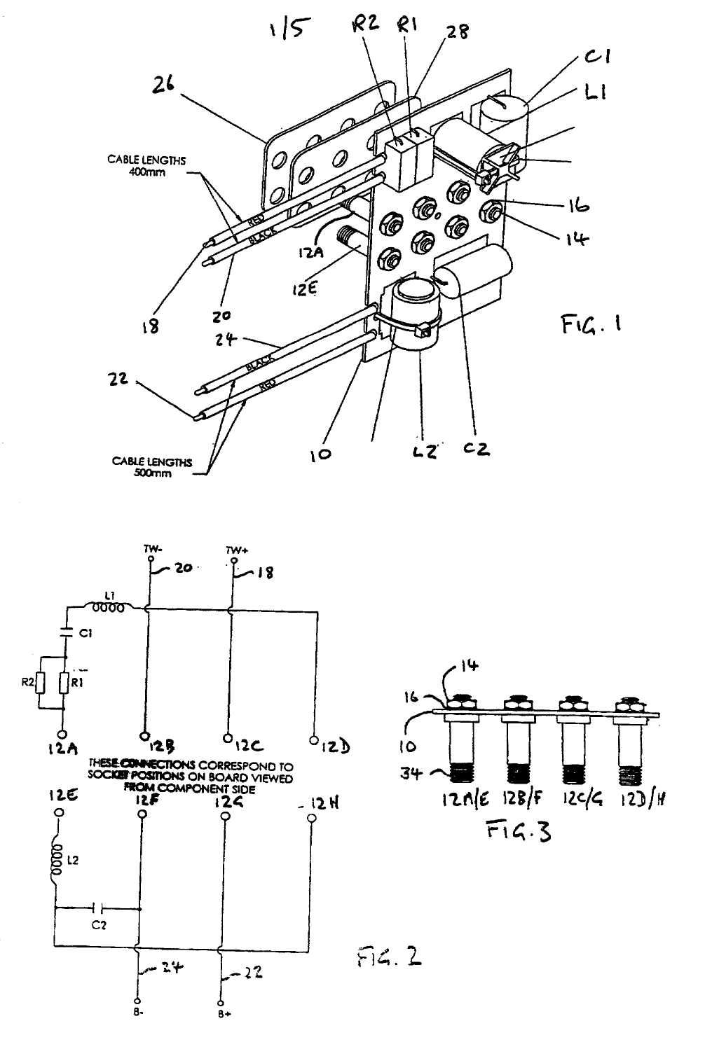

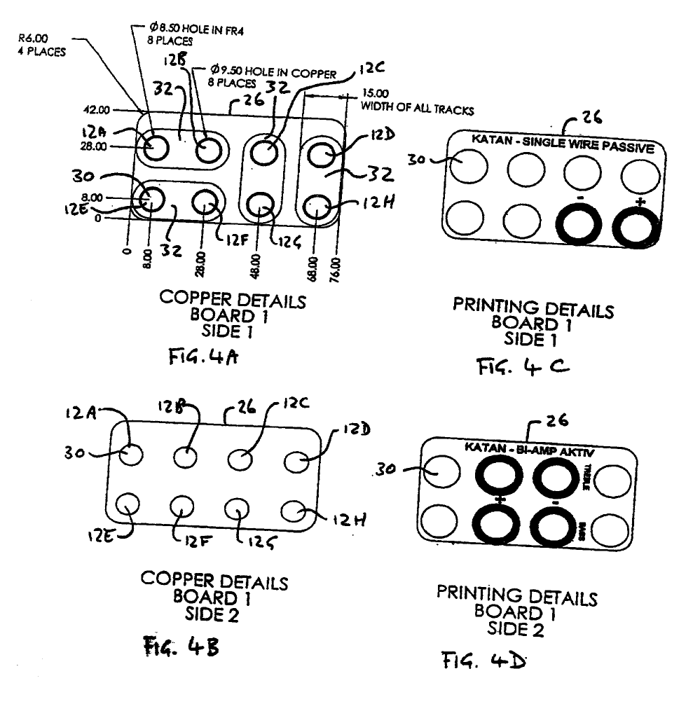

FIG. 3 is a side view of a set of terminals forming part of the assembly of FIG. 1;

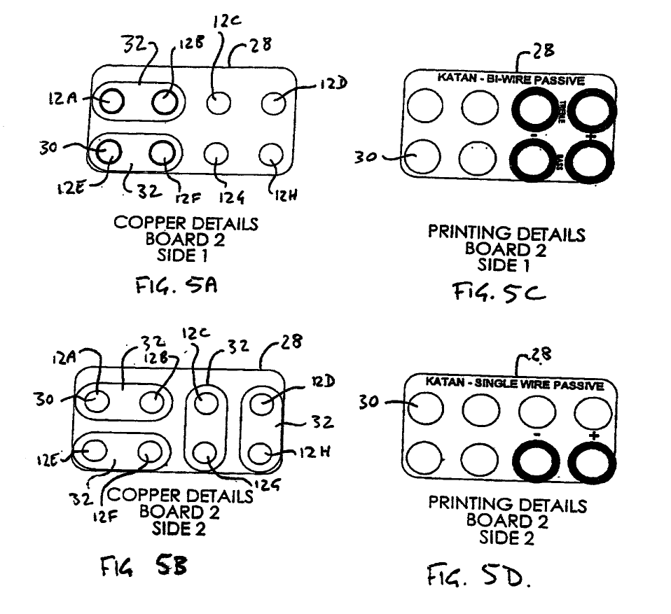

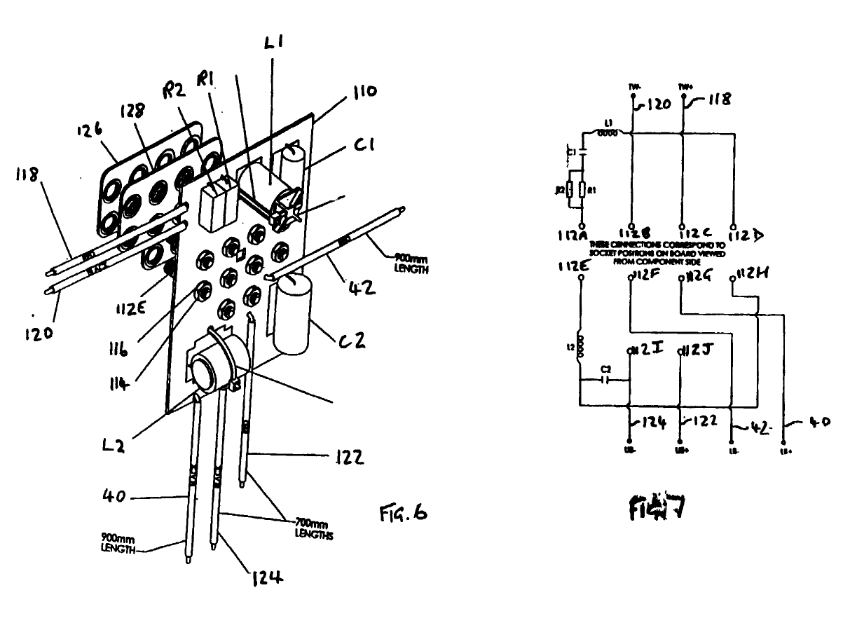

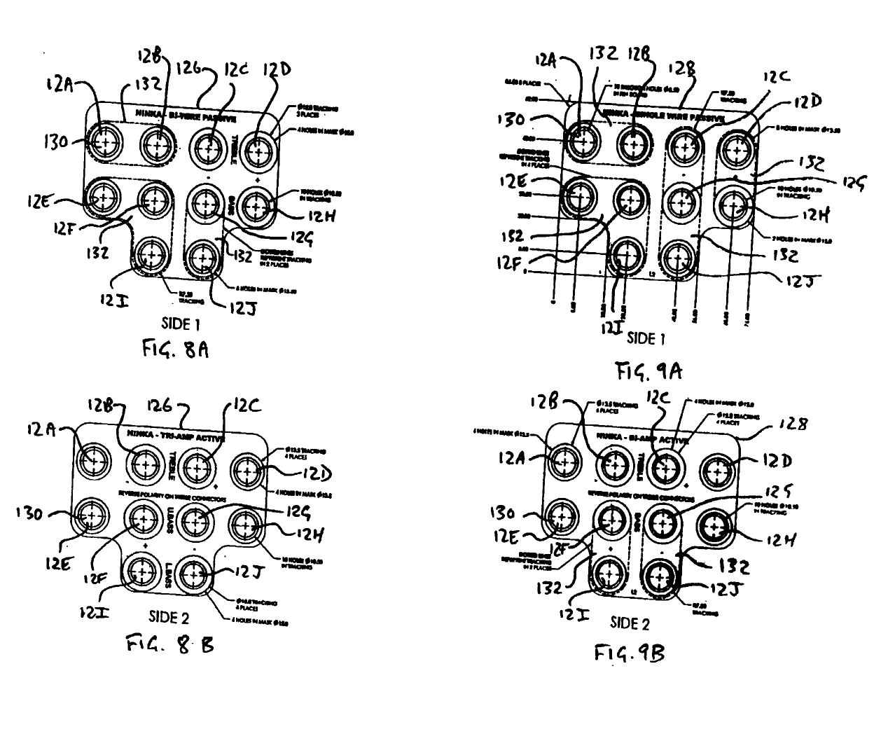

FIGS. 4A to 4D illustrate one of a pair of alternative connector board members for use with the assembly of FIG. 1;

FIGS. 5A to 5D illustrate a second of a pair of alternative connector board members for use with the assembly of FIG. 1;

FIG. 6 is a perspective view of a second embodiment of a terminal and passive crossover assembly for a three-driver loudspeaker, in accordance with the present invention;

FIG. 7 is a schematic circuit diagram of the assembly of FIG. 6;

FIGS. 8A and 8B illustrate one of a pair of alternative connector board members for use with the assembly of FIG. 6; and

FIGS. 9A and 9B illustrate a second of a pair of alternative connector board members for use with the assembly of FIG. 6.

Referring now to the drawings, FIGS. 1 to 5 illustrate a first embodiment of the invention, for use with a loudspeaker having two driver units. FIG. 1 shows a terminal and passive crossover assembly comprising a main printed circuit board (PCB) 10 upon which are mounted eight terminal pillars 12A-12H, secured to the PCB 10 by means of ruts 14 and star washers 16, and passive circuit components comprising first and second resistors R1 and R2, first and second capacitors C1 and C2 and first and second inductors L1 and L2. Cables 18 and 20 connect the PCB 10 to a treble driver unit (tweeter, not shown) and cables 22 and 24 connect the PCB 10 to a bass driver unit (woofer, not shown). The assembly further includes first and second alternative connector boards 26 and 28. The connector boards 26 and 28 are used to interconnect the various terminals 12A-12H in a variety of different configurations, as shall be described further below.

As can be seen from FIG. 2, the upper half of the assembly comprises a first set of terminals 12A-12D and crossover circuit R1, R2, C1, L1 associated with a tweeter and the bottom half of the assembly comprises a second set of terminals 12E-12H and crossover circuit C2, L2 associated with a woofer. In the upper half, the middle pair of terminals 12B and 12C are connected directly to the tweeter via cables 18 and 20 and the crossover circuit R1, R2, C1, L1 is connected between the remaining outer terminals 12A and 12D, electrically isolated from the tweeter. In the bottom half, the middle pair of terminals 12F and 12G are connected directly to the woofer via cables 22 and 24 and the crossover circuit C2, L2 is connected between the remaining outer terminals 12E and 12H, electrically isolated from the woofer.

This arrangement allows one or more amplifiers to be connected to the tweeter and woofer in a variety of configurations by selectively interconnecting pairs of the terminals 12A-12D and 12E-12H as follows:

For conventional single wire passive operation, a first one of the pair of amplifier output cables has to be connected to the tweeter via the upper crossover circuit R1, R2, C1 and C2 and to the woofer via the lower crossover circuit C2, L2, while the second amplifier output cable has to be connected directly to the tweeter and to the woofer. This can be accomplished by interconnecting the following pairs of terminals: 12A and 12B; 12E and 12F; 12C and 12G; and 12D and 12H. Now, if the first amplifier output is connected to either terminal 12D or 12H, it is also connected to the tweeter via the upper crossover circuit R1, R2, C1 and L1, terminal 12A and terminal 12B and to the woofer via the lower crossover circuit C2 and L2, terminal 12E and terminal 12F. If the second amplifier output is connected to either terminal 12C or 12G, it is also connected directly to the tweeter and the woofer.

For bi-wire passive operation, the upper and lower halves of the crossover have to remain electrically isolated, with a first cable of a first pair of amplifier output cables connected to the tweeter via the upper crossover circuit R1, R2, C1, L1 and a second cable of the first pair connected directly to the tweeter, and with a third cable of a second pair of amplifier output cables connected to the woofer via the lower crossover circuit C2, L2 and a fourth cable of the second pair connected directly to the woofer. This can be accomplished by interconnecting the following pairs of terminals: 12A and 12B; and 12E and 12F. Now, if the first pair of amplifier output cables are connected to terminals 12D and 12C, the first cable of the first pair is connected to the tweeter via the crossover circuit R1, R2, C1 and L1, terminal 12A and terminal 12B, whilst the second cable of the first pair is connected directly to the tweeter. If the second pair of amplifier output cables are connected to terminals 12H and 12G, the third cable of the second pair is connected to the woofer via the crossover circuit C2 and L2, terminal 12E and terminal 12F, whilst the fourth cable of the second pair is connected directly to the woofer.

For bi-amp active operation, using an active crossover upstream from the loudspeaker, the first pair of amplifier output cables may simply be connected to terminals 12B and 12C so as to be connected directly to the tweeter and the second pair of amplifier output cables may simply be connected to terminals 12F and 12G so as to be connected directly to the tweeter. No interconnections are required between any of the terminals 12A-12H.

The PCB 10 of FIG. 1 is mounted in the interior of the loudspeaker enclosure with the terminal pillars 12A-12H projecting outwardly through a rear panel of the enclosure. Accordingly, the terminal interconnections described above may be made externally of the loudspeaker enclosure, obviating any need to dismantle or disassemble the loudspeaker. The interconnections may be made by means of any suitable electrical conductors, such as jumper wires or jumper bars. However, it is preferred that the required interconnections are established using purpose-made connector boards 26 and 28 as shown in FIGS. 4A-4D and 5A-5D.

The boards 26 and 28 may be fabricated using known printed circuit board technology. Each of the boards has a set of apertures 30 corresponding to the terminals 12 of the crossover assembly, allowing the boards to be fitted over the terminal pillars on the rear panel of the loudspeaker enclosure. As described in more detail below, the boards have conductive tracks or pads 32 (usually of copper) interconnecting pairs of apertures 30, whereby various types of the interconnections are established between the various terminals 12 as described above. The boards are preferably double sided, having different interconnections (track patterns) on each side, so that each board may be used to provide two different sets of interconnections.

The electrical interconnections on one side of the boards 26, 28 are isolated from those on the other side of the boards. Electrical connections are established between the copper pads 32 and the terminal pillars 12 by means of nuts (not shown) which are screwed on to the threaded ends 34 of the terminal pillars and which contact areas of the copper pads 32 surrounding the apertures 30 and which also serve to secure the boards in place.

The surfaces of the boards 26 and 28 may also carry printed indicia, indicating the relevant mode of operation and the terminals to which the various amplifier outputs should be connected, as seen in FIGS. 4C and 4D and FIGS. 5C and 5D.

Referring to FIGS. 4A-4D, a first board 26 has a first side with a first set of interconnections as shown in FIG. 4A, suited for single wire passive operation. In the drawings, the apertures 30 of the boards 26 and 28 are labelled with reference numerals 12A-12H corresponding to the terminals of the crossover assembly which project through the apertures when the board is mounted on the terminal pillars with the respective side of the board facing outwards. Accordingly, in FIG. 4A, apertures 12A and 12B are interconnected by a first copper pad, apertures 12E and 12F by a second copper pad, apertures 12C and 12G by a third copper pad, and apertures 12D and 12H by a fourth copper pad. When mounted on the terminals, the board thus interconnects the various terminals for passive single wire operation as described above. In this example, the other side of the board 26 has no interconnections between apertures, and is suited for bi-amp active operation of the loudspeaker where the amplifier outputs are connected directly to the tweeter and woofer through terminals 12B/12C and 12F/12G as described above. In this case, the board 26 serves no electrical function, but simply carries markings indicating the mode of operation and the correct connections from the amplifier.

FIGS. 5A-5D illustrate a second connecting board 28. In this example, the first side of the board 28 as seen in FIG. SA has interconnections suitable for bi-wire, passive operation as described above. That is, apertures 12A and 12B are interconnected by a first copper pad and apertures 12E and 12F by a second copper pad. In this example, the second side of the second board 28 is identical to the first side of the first board 26, configured for single wire passive operation.

FIGS. 6 to 9 illustrate a second embodiment of the invention for a loudspeaker having three driver units (not shown), in this case a treble unit (tweeter), an upper bass unit (upper woofer) and a lower bass unit (lower woofer). Many of the components of this embodiment are similar to those of the first embodiment and are designated by the same reference numerals prefixed “1”, and will not be described in detail.

In this case, there are ten terminals 12A-12J, rather than eight as in the previous embodiment. Cables 122, 124 connect the terminals 112I and 112J directly to the upper bass unit and an extra pair of cables 40, 42 connect the terminals 12F and 12G directly to the lower bass unit. The connector boards 126 and 128 are different in shape from, but similar in construction and principle of operation to those of the first embodiment.

In the embodiment of FIGS. 6 to 9, the following wiring configurations are possible:

Bi-wire passive operation is enabled by making the following interconnections between terminals: 12A and 12B; 12E, 12F and 12I; 12G and 12J. A first pair of amplifier cables are connected to terminals 12C and 12D, so that one of the first pair of amplifier cables is connected directly to the tweeter via terminal 12C and the other of the first pair of amplifier cables is connected to the tweeter via terminal 12D, upper filter circuit L1, C1, R1, R2, terminal 12A and terminal 12B. A second pair of amplifier cables are connected to terminals 12G and 12H, so that one of the second pair of amplifier cables is connected directly to the upper woofer via terminals 12G and 12J and to the lower woofer via terminal 12G, whilst the other of the second pair of amplifier cables is connected to the upper woofer via terminal 12H the lower filter circuit C2, L2, and terminals 12E, 12F and 12I, and to the lower woofer via the terminal 12H the lower filter circuit C2, L2, and terminals 12E and 12F. These connections may be made using the first side of the first connector board 126 shown in FIG. 8A.

Tri-amp active operation requires no interconnections between terminals. A first amp is connected directly to the tweeter by a first pair of amplifier cables via terminals 12B and 12C, a second amp is connected directly to the upper woofer by a second pair of amplifier cables via terminals 12I and 12J, and a third amp is connected directly to the lower woofer by a third pair of amplifier cables via terminals 12F and 12G. The second side of the first connector 126 board has no interconnections between terminal apertures 130 and simply indicates the correct connections for tri-amp active operation.

Single-wire passive operation is enabled by making the following interconnections between terminals: 12A and 12B; 12C, 12G and 12J; 12D and 12H; 12E, 12F and 12I. If one of a pair of amplifier cables is connected to any one of terminals 12C, 12G or 12J, it is also connected directly to the tweeter, upper woofer and lower woofer. If the other of the pair of amplifier cables is connected to either of terminals 12D and 12H, it is also connected to the tweeter via the upper filter circuit L1, C1, R1, R2, terminal 12A and terminal 12B, to the upper woofer via the lower filter circuit L2, C2, terminal 12E, terminal 12F and terminal 12I, and to the lower woofer via the lower filter circuit L2, C2, terminal 12E and terminal 12F. These connections may be made using the first side of the second connector board 128 shown in FIG. 9A.

Bi-amp active operation may be enabled by making the following interconnections between terminals: 12F and 12I; 12G and 12J. If a first pair of amplifier cables is connected to terminals 12B and 12C, then the first pair of cables is connected directly to the tweeter. If one of a second pair of amplifier cables is connected to either one of terminals 12F and 12I and the other of the second pair of amplifier cables is connected to either one of terminals 12G and 12J, then the second pair of amplifier cables is connected directly to the upper and lower woofers. These connections may be made using the second side of the second connector board 128 shown in FIG. 9B.

The invention can be applied to other loudspeakers having different numbers and/or combinations of driver units.

Improvements and modifications may be incorporated without departing from the scope of the invention as defined in the claims appended hereto.

1. An audio loudspeaker comprising:
an enclosure;
at least two driver units mounted within said enclosure;
crossover circuitry located inside said enclosure; and
a plurality of input terminals located on the exterior of said enclosure; wherein:
said input terminals include a first pair of first terminals for each of said driver units, each of said first pairs of first terminals being connected directly to a respective one of said driver units; a second pair of second terminals having a first crossover circuit connected therebetween and normally electrically isolated from said driver units; and a third pair of third terminals having a second crossover circuit connected therebetween and normally electrically isolated from said driver units.

2. An audio loudspeaker as claimed in claim 1, further including at least one connector element for interconnecting selected ones of said first, second a third terminals, externally of said enclosure, whereby said crossover circuits may be selectively connected in circuit between one or more of said first terminals and one or more of said driver units.

3. An audio loudspeaker as claimed in claim 2, wherein said connector element comprises a generally planar member having a plurality of apertures therein corresponding in number and position to said plurality of input terminals, whereby said planar member may be mounted on said terminals with said terminals projecting through said apertures, said planar member having electrically conductive elements on at least one side thereof interconnecting selected ones of said apertures in a predetermined configuration.

4. An audio loudspeaker as claimed in claim 3, wherein said planar member has different patterns of electrically conductive elements on each side thereof interconnecting selected ones of said apertures in different predetermined configurations.

5. An audio loudspeaker as claimed in claim 3 or claim 4, wherein said planar member is provided with indicia on at least one side thereof indicating a mode of loudspeaker operation corresponding to the pattern of electrically conductive elements thereon, if any, and indicating the terminals to which amplifier connections should be made.

6. A connector board for use with an audio loudspeaker as claimed in any preceding claim, said connector board comprising a generally planar member having a plurality of apertures therein corresponding in number and position to said plurality of input terminals of said loudspeaker, whereby said planar member may be mounted on said terminals with said terminals projecting through said apertures, said planar member having electrically conductive elements on at least one side thereof interconnecting selected ones of said apertures in a predetermined configuration.

7. A connector board as claimed in claim 6, wherein said planar member has different patterns of electrically conductive elements on each side thereof interconnecting selected ones of said apertures in different predetermined configurations.

8. A connector as claimed in claim 6 or claim 7, wherein said planar member is provided with indicia on at least one side thereof indicating a mode of loudspeaker operation corresponding to the pattern of electrically conductive means thereon, if any, and indicating the terminals to which amplifier connections should be made.
